(19) United States
(12) Patent Application Publication
(10) Pub. No.: US 2022/0282152 A1
(43) Pub. Date: Sep. 8, 2022

(54) ELECTRO-LUMINESCENT MATERIAL AND ELECTRO-LUMINESCENT DEVICE

(71) Applicant: NEXDOT, Romainville (FR)

(72) Inventors: Michele D'AMICO, Romainville (FR); Alexis KUNTZMANN, Clichy La Garenne (FR); Yu-Pu LIN, Versailles (FR); Vladyslav VAKARIN, Palaiseau (FR)

(73) Assignee: NEXDOT, Romainville (FR)

(21) Appl. No.: 17/632,692

(22) PCT Filed: Jul. 31, 2020
(86) PCT No.: PCT/EP2020/071651

§ 371 Date: Feb. 3, 2022

(30) Foreign Application Priority Data
Aug. 5, 2019 (EP) 19190095.0

(51) Int. Cl. C09K 11/88; C09K 11/56; C09K 11/02; H05B 33/14

(52) U.S. Cl. CPC C09K 11/883; C09K 11/565; C09K 11/025; H05B 33/145

(57) ABSTRACT

An electro-luminescent film including a substrate and anisotropic semiconductor nanoparticles distributed on the substrate according to a periodic pattern. The semiconductor nanoparticles have an aspect ratio greater than 1.5, and the repetition unit of the pattern has a smallest dimension of less than 500 micrometer and includes at least one pixel. Also, a process for the manufacture of the electro-luminescent film, and a light emitting device that includes the electro-luminescent film.

### FIELD OF INVENTION

The present invention pertains to the field of electro-luminescent materials. In particular, the invention relates to an electro-luminescent film, a process to prepare an electro-luminescent film and a light emitting device comprising an electro-luminescent film.

### BACKGROUND OF INVENTION

To represent colors in all their variety, one proceeds typically by additive synthesis of at least three complementary colors, especially red, green and blue. In a chromaticity diagram, the subset of available colors obtained by mixing different proportions of these three colors is formed by the triangle formed by the three coordinates associated with the three colors red, green and blue. This subset constitutes what is called a gamut.

A luminescent display device has to represent the widest possible gamut for an accurate color reproduction. For this, the composing sub-pixels must be of the most saturated colors possible. A light source has a saturated color if it is close to a monochromatic color. From a spectral point of view, this means that light emitted by the source is comprised of a single luminescence narrow band. A highly saturated shade has a vivid, intense color while a less saturated shade appears rather bland and gray.

It is therefore important to have light sources whose emission spectra are narrow and with saturated colors.

Semiconductor nanoparticles, commonly called “quantum dots”, are known as emissive material. Said objects have a narrow luminescence spectrum, approximately 30 nm full width at half maximum, and offer the possibility to tune their light emission in the entire visible spectrum as well as in infrared range after electric charges injection. Electrical current is forced into semiconductor nanoparticles, which energy eventually relax by emission of light.

Document US 2019/040,313 discloses fluorescent films comprising composite particles encapsulating semiconductor nanoplatelets in an inorganic material. Said films are not electro-luminescent films; indeed, the encapsulation of semiconductor nanoplatelets in a composite particle prevents the direct electrons injection into the semiconductor nanoplatelets because the encapsulating material acts as an insulator around the nanoplatelets.

Document U.S. Pat. No. 9,975,764 discloses films comprising latex particles deposited on an electret substrate. Said films are not electro-luminescent films as latex particles are not suitable for electrons injection.

It is known to use nanoplatelets to obtain great spectral emission bandwidth and a perfect control of the emission wavelength (see WO2013/140083).

However, distributing such semiconductor nanoparticles on a periodic pattern with well controlled size, i.e. size of nanoparticles deposit and/or size of pattern, is still an unmet challenge. For example, inkjet printing is not suitable to obtain a small repetition unit of a pattern (i.e. less than 500 micrometer) and comprising at least one pixel. Moreover the ink-jet technique is time consuming, considering that the deposition in general is not parallelized and also the constraints about the viscosity and nature of the used solvents are quite strong.

It is therefore an object of the present invention to provide an electro-luminescent film having well controlled periodic pattern, which can be used as elementary brick for various light emitting devices, like display devices.

### SUMMARY

This invention thus relates to an electro-luminescent film comprising a substrate and semiconductor nanoparticles distributed on the substrate according to a periodic pattern, wherein semiconductor nanoparticles have an aspect ratio greater than 1.5; wherein the repetition unit of the pattern has a smallest dimension of less than 500 micrometer and comprises at least one pixel.

According to an embodiment, the pattern is periodic in two dimensions, preferably the periodic pattern is a rectangular lattice or a square lattice.

According to an embodiment, semiconductor nanoparticles are inorganic, preferably semiconductor nanoparticles are semiconductor nanocrystals comprising a material of formula MₓQ_{y}E_{z}A_{w}, wherein: M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs; Q is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs; E is selected from the group consisting of O, S, Se, Te, C, N, P, As, Sb, F, Cl, Br, I; A is selected from the group consisting of O, S, Se, Te, C, N, P, As, Sb, F, Cl, Br, I; and x, y, z and w are independently a rational number from 0 to 5; x, y, z and w are not simultaneously equal to 0; x and y are not simultaneously equal to 0; z and w are not simultaneously equal to 0.

According to an embodiment, semiconductor nanoparticles have a longest dimension greater than 25 nanometers, preferably greater than 35 nm.

According to an embodiment, semiconductor nanoparticles are on the substrate with their longest dimension substantially aligned in a predetermined direction.

According to an embodiment, substrate is selected from a conductive material and a semi-conductive material.

According to an embodiment, semiconductor nanoparticles on the substrate form layers with a thickness of less than 100 nm.

According to an embodiment, the repetition unit of the periodic pattern comprises at least two pixels, preferably, semiconductor nanoparticles on the first pixel of the at least two pixels are different from semiconductor nanoparticles on the second pixel of the at least two pixels.

The invention also relates to a first process for the manufacture of an electro-luminescent film comprising a substrate and semiconductor nanoparticles distributed on the substrate according to a periodic pattern, wherein the repetition unit of the pattern has a smallest dimension of less than 500 micrometer and comprises at least one pixel comprising the steps of.
i) providing an electret substrate;
ii) writing a surface electric potential on the electret substrate according to the pattern, so that at least one pixel of the repetition unit is written in the whole pattern; and
iii) bringing the electret substrate in contact with a colloidal dispersion of semiconductor nanoparticles having an aspect ratio greater than 1.5 for a contacting time of less than 15 minutes.

The invention also relates to a second process for the manufacture of an electro-luminescent film comprising a substrate and semiconductor nanoparticles distributed on the substrate according to a periodic pattern, wherein the repetition unit of the pattern has a smallest dimension of less than 500 micrometer and comprises at least two pixels and wherein semiconductor nanoparticles on the first pixel of the at least two pixels are different from semiconductor nanoparticles on the second pixel of the at least two pixels comprising the steps of.
i) providing an electret substrate;
ii) writing a surface electric potential on the electret substrate according to the pattern, so that the first pixel of the repetition unit is written in the whole pattern;
iii) bringing the electret substrate in contact with a colloidal dispersion of semiconductor nanoparticles having an aspect ratio greater than 1.5 for a contacting time of less than 15 minutes;
iv) drying the electret substrate and semiconductor nanoparticles deposited thereon to form an intermediate structure;
v) writing a surface electric potential on the intermediate structure according to the pattern, so that the second pixel of the repetition unit is written in the whole pattern; and
vi) bringing the electret substrate in contact with a colloidal dispersion of semiconductor nanoparticles an aspect ratio greater than 1.5 and different from those used in step iii) for a contacting time of less than 15 minutes.

The invention also relates to a third process for the manufacture of an electro-luminescent film comprising a substrate and semiconductor nanoparticles distributed on the substrate according to a periodic pattern, wherein the repetition unit of the pattern has a smallest dimension of less than 500 micrometer and comprises at least one pixel comprising the steps of:
i) Providing a substrate;
ii) Inducing a surface electric potential on the substrate according to the pattern, so that at least one pixel of the repetition unit is induced in the whole pattern; and
iii) Bringing the substrate in contact with a colloidal dispersion of semiconductor nanoparticles having an aspect ratio greater than 1.5 for a contacting time of less than 15 minutes, while surface electric potential is maintained.

The invention also relates to a fourth process for the manufacture of an electro-luminescent film comprising a substrate and semiconductor nanoparticles deposited on the substrate according to a periodic pattern, wherein the repetition unit of the pattern has a smallest dimension of less than 500 micrometer and comprises at least two pixels and wherein semiconductor nanoparticles on the first pixel of the at least two pixels are different from semiconductor nanoparticles on the second pixel of the at least two pixels comprising the steps of:
i) Providing a substrate;
ii) Inducing a surface electric potential on the substrate according to the pattern, so that the first pixel of the repetition unit is induced in the whole pattern;
iii) Bringing the substrate in contact with a colloidal dispersion of semiconductor nanoparticles having an aspect ratio greater than 1.5 for a contacting time of less than 15 minutes, while surface electric potential is maintained;
iv) Drying the substrate and semiconductor nanoparticles deposited thereon to form an intermediate structure;
v) Inducing a surface electric potential on the intermediate structure according to the pattern, so that the second pixel of the repetition unit is induced in the whole pattern; and
vi) Bringing the substrate in contact with a colloidal dispersion of semiconductor nanoparticles having an aspect ratio greater than 1.5 and different from those used in step iii) for a contacting time of less than 15 minutes, while surface electric potential is maintained.

The invention further relates to a light emitting device comprising an electro-luminescent film comprising a substrate and semiconductor nanoparticles on the substrate according to a periodic pattern, wherein semiconductor nanoparticles have an aspect ratio greater than 1.5; wherein the repetition unit of the pattern has a smallest dimension of less than 500 micrometer and comprises at least one pixel.

### Definitions

In the present invention, the following terms have the following meanings:
“aspect ratio” is a feature of anisotropic particles. An anisotropic particle has three characteristic dimensions, one of which is the longest and one of which is the shortest. Aspect ratio of an anisotropic particle is the ratio of the longest dimension divided by the shortest dimension. Aspect ratio is necessarily greater than 1. For instance, a nanoparticle of length L=30 nm, width W=20 nm and thickness T=10 nm has an aspect ratio of L/T=3, as shown on FIG. 2. Shape factor is a synonym of aspect ratio.
“blue range” refers to the range of wavelength from 400 nm to 500 nm.
“colloidal” refers to a substance in which particles are dispersed, suspended and do not settle, flocculate or aggregate; or would take a very long time to settle appreciably, but are not soluble in said substance.
“colloidal nanoparticles” refers to nanoparticles that may be dispersed, suspended and which would not settle, flocculate or aggregate; or would take a very long time to settle appreciably in another substance, typically in an aqueous or organic solvent, and which are not soluble in said substance. “Colloidal nanoparticles” does not refer to particles grown on substrate.
“core/shell” refers to heterogeneous nanostructure comprising an inner part: the core, overcoated on its surface, totally or partially, by a film or a layer of at least one atom thick material different from the core: the shell. Core/shell structures are noted as follows: core material/shell material. For instance, a particle comprising a core of CdSe and a shell of ZnS is noted CdSe/ZnS. By extension, core/shell/shell structures are defined as core/first-shell structures overcoated on their surface, totally or partially, by a film or a layer of at least one atom thick material different from the core and/or from the first shell: the second-shell. For instance, a particle comprising a core of CdSe_{0.45}S_{0.55}, a first-shell of Cd_{0.80}Zn_{0.20}S and a second-shell of ZnS is noted CdSe_{0.45}S_{0.55}/Cd_{0.80}Zn_{0.20}S/ZnS.
“display device” refers to a device that displays an image signal. Display devices include all devices that display an image such as, non-limitatively, a television, a computer monitor, a personal digital assistant, a mobile phone, a laptop computer, a tablet PC, a tablet phone, a foldable tablet phone, an MP3 player, a CD player, a DVD player, a Blu-Ray player, a projector, a head mounted display, a smart watch, a watch phone or a smart device.
“electret” refers to a material able to have a non-zero polarization density (i.e. the material contains electric dipole moments) for a long time, without external electric field. Polarization density may be created by injection of electric charges in material, said charges creating polarization density. In an electret material, dissipation of polarization density is slow (as compared to conductive materials), typically from tens of seconds to tens of minutes. To the purpose of the invention, the stability of polarization should be bigger than 1 minute.
“electro-luminescent” refers to the property of a material that emits light when electric current flows in the material. Actually, electric current drives said material in an excited state, which eventually relaxes by emission of light.
“external quantum efficiency” refers to the ratio of extracted photons over injected carriers in a material.
“FWHM” refers to Full Width at Half Maximum for a band of emission/absorption of light.
“green range” refers to the range of wavelength from 500 nm to 600 nm.
“MₓE_{z}” refers to a material composed of chemical element M and chemical element E, with a stoichiometry of x elements of M for z elements of E, x and z being independently a decimal number from 0 to 5; x and z not being simultaneously equal to 0. The stoichiometry of MₓE_{z} is not strictly limited to x:z but includes slight variations in composition due to nanometric size of nanoparticles, crystalline face effect and potentially doping. Actually, MₓE_{z} defines material with M content in atomic composition between x−5% and x+5%; with E content in atomic composition between z−5% and z+5%; and with atomic composition of compounds different from M or E from 0.001% to 5%. Same principle applies for materials composed of three of four chemical elements.
“nanoparticle” refers to a particle having at least one dimension in the 0.1 to 100 nanometers range. Nanoparticles may have any shape. A nanoparticle may be a single particle or an aggregate of several single particles. Single particles may be crystalline. Single particles may have a core/shell or plate/crown structure.
“nanoplatelet” refers to a nanoparticle having a 2D-shape, i.e. having one dimension smaller than the two others; said smaller dimension ranging from 0.1 to 100 nanometers. In the sense of the present invention, the smallest dimension (hereafter referred to as the thickness) is smaller than the other two dimensions (hereafter referred to as the length and the width) by a factor (aspect ratio) of at least 1.5. FIG. 3 shows various nanoplatelets.
“periodic pattern” refers to an organization of a surface on which a geometric element is repeated regularly, the length of repetition being the period. Lattices are specific periodic patterns.
“pixel” refers to a geometrical area in a repetition unit. By extension, if nanoparticles are on said area and form a volume of material: this volume is also a pixel. In particular, a pixel may be a sub-unit of a repetition unit.
“red range” refers to the range of wavelength from 600 nm to 720 nm.
“repetition unit” refers to a single geometric element that is repeated in a periodic pattern.

### DETAILED DESCRIPTION

The following detailed description will be better understood when read in conjunction with the drawings. For the purpose of illustrating, the electro-luminescent film is shown in a preferred embodiment. It should be understood, however that the application is not limited to the precise arrangements, structures, features, embodiments, and aspect shown. The drawings are not drawn to scale and are not intended to limit the scope of the claims to the embodiments depicted. Accordingly, it should be understood that where features mentioned in the appended claims are followed by reference signs, such signs are included solely for the purpose of enhancing the intelligibility of the claims and are in no way limiting on the scope of the claims.

This invention relates to an electro-luminescent film comprising a substrate and semiconductor nanoparticles distributed on the substrate according to a periodic pattern. The repetition unit of the pattern has a smallest dimension of less than 500 micrometer.

In some embodiments, the smallest dimension of the repetition unit of the pattern is less than 300 micrometer, less than 200 micrometer, less than 100 micrometer, less than 80 micrometer, less than 50 micrometer, less than 40 micrometer, less than 30 micrometer. Preferably, the smallest dimension of the repetition unit is greater than 3 micrometer, preferably greater than 5 micrometer, more preferably greater than 10 micrometer. Indeed, repetition unit size should be large enough to avoid diffraction or scattering of light emitted by semiconductor nanoparticles.

The electro-luminescent film is illustrated in FIG. 1.

In the invention, the repetition unit of the periodic pattern comprises at least one pixel. A pixel is actually a sub unit of the repetition unit. Semiconductor nanoparticles are localized on the area defined by said pixel. Consequently, electro-luminescent film of the invention comprises deposits of semiconductor nanoparticles distributed on a periodic pattern. Preferably, the smallest dimension of the pixel is greater than 3 micrometer. Indeed, pixel size should be large enough to avoid diffraction or scattering of light emitted by semiconductor nanoparticles which constitute pixels.

In the invention, semiconductor nanoparticles are anisotropic and have an aspect ratio greater than 1.5. In some embodiments, semiconductor nanoparticles have an aspect ratio greater than 1.5, 2, 2.5, 3, 3.5, 4, 4.5, 5, 6, 7, 8, 9, 10, 15, 20. Semiconductor nanoparticles may have an ovoid shape, a discoidal shape, a cylindrical shape, a faceted shape, a hexagonal shape, a triangular shape, or a platelet shape. Anisotropic particles present the following advantage: along their smallest dimension, they define a quantum effect which is not affected by their longest dimension. With anisotropic particles, it is possible to have one dimension of 1 to 1.2 nm yielding the quantum effect expected in blue range and another dimension much longer, for instance greater than 10 nm, allowing to manage stability of particles and to tune optical properties of particles. Moreover, controlling the size of only one dimension, i.e. thickness for nanoplatelets, is easier than controlling sizes in three dimensions, as it is required for spherical quantum dots. Last, FWHM of emission spectra of semiconductor nanoplatelets is lower than for quantum dots: emission bands are narrower, and the typical photoluminescence decay time of semiconductor nanoplatelets is 1 order of magnitude faster than for spherical quantum dots.

Preferably, the semiconductor nanoparticles have a 1D shape (cylindrical shape) or a 2D shape (platelet shape). Advantageously, a 1D shape allows confinement of excitons in two dimensions and allows free propagation in the other dimension, a 2D shape allows confinement of excitons in one dimension and allows free propagation in the other two dimensions, whereas a quantum dot (or spherical nanocrystal) has a 3D shape and allow confinement of excitons in all three spatial dimensions. These particular 2D and 1D confinements result in distinct electronic and optical properties, for example a faster photoluminescence decay time and a narrower optical feature with full width at half maximum (FWHM) much lower than for spherical quantum dots.

It is worth noting that quantum dots and semiconductor nanoplatelets are quite different regarding their optical properties, but also regarding their morphology and their surface chemistry:
the organization of M and E atoms (for a formula MₓE_{z}) at the surface of a nanoplatelet and at the surface of a quantum dot are different;
the organization of surface ligands is thus also different;
nanoplatelets have specific exposed crystalline facets different from quantum dots; and
nanoplatelets have a higher specific surface than quantum dots (this is valid for a nanoplatelet having a thickness R and a quantum dot having the same diameter R, wherein lateral dimensions of the nanoplatelet being superior to 5/3R).

According to an embodiment, the pattern is periodic in two dimensions, preferably the periodic pattern is a rectangular lattice or a square lattice. Such periodic patterns allow for easy localization of each elementary unit on the electro-luminescent film, which is desirable to address electrically each elementary unit.

According to an embodiment, semiconductor nanoparticles are inorganic, in particular, semiconductor nanoparticles may be semiconductor nanocrystals comprising a material of formula

MₓQ_{y}E_{z}A_{w} (I)

wherein:

M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs;

Q is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs;

E is selected from the group consisting of O, S, Se, Te, C, N, P, As, Sb, F, Cl, Br, I;

A is selected from the group consisting of O, S, Se, Te, C, N, P, As, Sb, F, Cl, Br, I; and

x, y, z and w are independently a decimal number from 0 to 5; x, y, z and w are not simultaneously equal to 0; x and y are not simultaneously equal to 0; z and w may not be simultaneously equal to 0. Preferably, semiconductor nanoparticles have one of their dimensions lower than the Bohr radius of electron-hole pair in the material.

Herein, the formulas MₓQ_{y}E_{z}A_{w} (I) and MₓN_{y}E_{z}A_{w} can be used interchangeably (wherein Q or N is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs).

In one embodiment, semiconductor nanoparticles comprise a semiconductor material selected from the group consisting of group IV, group IIIA-VA, group IIA-VIA, group IIIA-VIA, group IA-IIIA-VIA, group IIA-VA, group IVA-VIA, group VIB-VIA, group VB-VIA, group IVB-VIA or mixture thereof.

In a specific configuration of this embodiment, semiconductor nanocrystals have a homostructure. By homostructure, it is meant that each particle is homogenous and has the same local composition in all its volume. In other words, each particle is a core particle without a shell.

In a specific configuration of this embodiment, semiconductor nanocrystals have a core/shell structure. The core comprises a material of formula MₓQ_{y}E_{z}A_{w} as defined above. The shell comprises a material different from core of formula MₓQ_{y}E_{z}A_{w} as defined above, such as a material of formula

M′_{x′}Q′_{y′}E′_{z′}A′_{w′} (II)

wherein:

M′ is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs;

Q′ is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs;

E′ is selected from the group consisting of O, S, Se, Te, C, N, P, As, Sb, F, Cl, Br, I;

A′ is selected from the group consisting of O, S, Se, Te, C, N, P, As, Sb, F, Cl, Br, I; and

x′, y′, z′ and w are independently a decimal number from 0 to 5; x′, y′, z′ and w′ are not simultaneously equal to 0; x′ and y′ are not simultaneously equal to 0; z′ and w′ may not be simultaneously equal to 0.

In a more specific configuration of this embodiment, semiconductor nanocrystals have a core/first-shell/second-shell structure (i.e. core/shell/shell structure). The core comprises a material of formula MₓQ_{y}E_{z}A_{w} as defined above. The first-shell comprises a material different from core of formula MₓQ_{y}E_{z}A_{w} as defined above. The second-shell is deposited partially or totally on the first-shell with the same features, or different features than the first-shell, such as for example same or different thickness. The material of second-shell is different from the material of the first shell and/or of the material of the core. By analogy, structures with three or four shells may be prepared.

In a specific configuration of this embodiment, semiconductor nanocrystals have a core/crown structure. The embodiments concerning shells apply mutatis mutandis to crowns in terms of composition, thickness, properties, number of layers of material.

In a configuration of this embodiment, semiconductor nanoparticles are colloidal nanoparticles.

In a configuration of this embodiment, semiconductor nanoparticles are electrically neutral. With electrically neutral semiconductor nanoparticles, it is easier to manage deposition on substrate, especially when deposition is driven by electrical polarization.

In a specific configuration of this embodiment, semiconductor nanoparticles emit red light when stimulated electrically. Emitted red light is typically a band centered on a wavelength shorter than 720 nm and longer than 600 nm, preferably shorter than 670 nm and longer than 620 nm, more preferably shorter than 635 nm and longer than 625 nm. Emitted red light is typically a band having a FWHM less than 50 nm, preferably less than 30 nm, more preferably less than 20 nm, i.e. a FWHM less than 0.16 eV, preferably less than 0.096 eV, more preferably less than 0.064 eV.

In a specific configuration of this embodiment, semiconductor nanoparticles emit green light when stimulated electrically. Emitted green light is typically a band centered on a wavelength shorter than 600 nm and longer than 500 nm, preferably shorter than 550 nm and longer than 520 nm, more preferably shorter than 535 nm and longer than 525 nm. Emitted green light is typically a band having a FWHM less than 50 nm, preferably less than 30 nm, more preferably less than 20 nm, i.e. FWHM less than 0.22 eV, preferably less than 0.13 eV, more preferably less than 0.08 eV.

In a specific configuration of this embodiment, semiconductor nanoparticles emit blue light when stimulated electrically. Emitted blue light is typically a band centered on a wavelength shorter than 500 nm and longer than 400 nm, preferably shorter than 480 nm and longer than 420 nm, more preferably shorter than 455 nm and longer than 435 nm. Emitted blue light is typically a band having a FWHM less than 50 nm, preferably less than 30 nm, more preferably less than 20 nm, i.e. a FWHM less than 0.306 eV, preferably less than 0.184 eV, more preferably less than 0.122 eV.

In a configuration of this embodiment, semiconductor nanoparticles are selected from CdSeₓS₍₁₋ₓ₎/CdS/ZnS, CdSeₓS₍₁₋ₓ₎/Cd_{y}Zn_{(1-y)}S, CdSeₓS₍₁₋ₓ₎/ZnS, CdSeₓS₍₁₋ₓ₎/Cd_{y}Zn_{(1-y)}S/ZnS, CdSeₓS₍₁₋ₓ₎/CdS, CdSe/CdS/ZnS, CdSe/CdS, CdSe/Cd_{y}Zn_{(1-y)}S, CdSe/Cd_{y}Zn_{(1-y)}S/ZnS, CdSeₓS₍₁₋ₓ₎/CdS/ZnSe, CdSeₓS₍₁₋ₓ₎/Cd_{y}Zn_{(1-y)}Se, CdSeₓS₍₁₋ₓ₎/ZnSe, CdSeₓS₍₁₋ₓ₎/Cd_{y}Zn_{(1-y)}Se/ZnSe, CdSeₓS₍₁₋ₓ₎/Cd_{y}Zn_{(1-y)}Se/ZnS, CdSe/CdS/ZnSe, CdSe/Cd_{y}Zn_{(1-y)}Se, CdSe/Cd_{y}Zn_{(1-y)}Se/ZnSe CdSe/Cd_{y}Zn_{(1-y)}Se/ZnS, CdSeₓS₍₁₋ₓ₎/CdS/ZnSe_{y}S_{(1-y)}, CdSeₓS₍₁₋ₓ₎/Cd_{y}Zn_{(1-y)}S, CdSeₓS₍₁₋ₓ₎/ZnSe_{y}S_{(1-y)}, CdSeₓS₍₁₋ₓ₎/Cd_{y}Zn_{(1-y)}S/ZnSe_{z}S_{(1-z)}, CdSeₓS₍₁₋ₓ)/CdS, CdSe/CdS/ZnSe_{y}S_{(1-y)}, CdSe/CdS, CdSe/Cd_{y}Zn_{(1-y)}S, CdSe/Cd_{y}Zn_{(1-y)}S/ZnSe_{z}S_{(1-z)}, CdSeₓS₍₁₋ₓ₎/CdS/ZnSe_{y}S_{(1-y)}, CdSeₓS₍₁₋ₓ₎/Cd_{y}Zn_{(1-y)}Se, CdSeₓS₍₁₋ₓ₎/ZnSe_{y}S_{(1-y)}, CdSeₓS₍₁₋ₓ₎/Cd_{y}Zn_{(1-y)}Se/ZnSe_{z}S_{(1-z)}, CdSeₓS₍₁₋ₓ₎/Cd_{y}Zn_{(1-y)}Se/ZnSe_{z}S_{(1-z)}, CdSe/Cd_{y}Zn_{(1-y)}Se, CdSe/Cd_{y}Zn_{(1-y)}Se/ZnSe_{z}S_{(1-z)}, CdSe/Cd_{y}Zn_{(1-y)}Se/ZnSe_{z}S_{(1-z)} where x, y and z are rational numbers between 0 (excluded) and 1 (excluded), and emit red light when stimulated electrically. Emitted red light is typically a band centered on a wavelength shorter than 720 nm and longer than 600 nm, preferably shorter than 670 nm and longer than 620 nm, more preferably shorter than 635 nm and longer than 625 nm. Emitted red light is typically a band having a FWHM less than 50 nm, preferably less than 30 nm, more preferably less than 20 nm. Suitable semiconductor nanoparticles emitting red light at 630 nm are core/shell/shell nanoplatelets of CdSe_{0.45}S_{0.55}/Cd_{0.30}Zn_{0.70}S/ZnS, with a core of thickness 1.2 nm and a lateral dimension, i.e. length or width, greater than 8 nm and shells of thicknesses 2.5 nm and 2 nm. Other suitable semiconductor nanoparticles emitting red light at 630 nm are core/shell/shell nanoplatelets of CdSe_{0.65}S_{0.35}/CdS/ZnS, with a core of thickness 1.2 nm and a lateral dimension, i.e. length or width, greater than 8 nm and shells of thicknesses 2.5 nm and 2 nm.

In a configuration of this embodiment, semiconductor nanoparticles are selected from CdSeₓS₍₁₋ₓ₎/CdS/ZnS, CdSeₓS₍₁₋ₓ₎/Cd_{y}Zn_{(1-y)}S, CdSeₓS₍₁₋ₓ₎/ZnS, CdSeₓS₍₁₋ₓ₎/Cd_{y}Zn_{(1-y)}S/ZnS, CdSeₓS₍₁₋ₓ₎/CdS, CdSe/CdS/ZnS, CdSe/CdS, CdSe/Cd_{y}Zn_{(1-y)}S, CdSe/Cd_{y}Zn_{(1-y)}S/ZnS, CdSeₓS₍₁₋ₓ₎/CdS/ZnSe, CdSeₓS₍₁₋ₓ₎/Cd_{y}Zn_{(1-y)}Se, CdSeₓS₍₁₋ₓ₎/ZnSe, CdSeₓS₍₁₋ₓ₎/Cd_{y}Zn_{(1-y)}Se/ZnSe, CdSeₓS₍₁₋ₓ₎/Cd_{y}Zn_{(1-y)}Se/ZnS, CdSe/CdS/ZnSe, CdSe/Cd_{y}Zn_{(1-y)}Se, CdSe/Cd_{y}Zn_{(1-y)}Se/ZnSe CdSe/Cd_{y}Zn_{(1-y)}Se/ZnS, CdS/ZnSe, CdSeₓS₍₁₋ₓ₎/ZnS/Cd_{y}Zn_{(1-y)}S/ZnS, CdS/ZnS, CdS/Cd_{y}Zn_{(1-y)}S, CdS/Cd_{y}Zn_{(1-y)}S/ZnS, CdS/ZnSe, CdS/Cd_{y}Zn_{(1-y)}Se, CdS/ZnSe, CdS/Cd_{y}Zn_{(1-y)}Se/ZnSe, CdS/Cd_{y}Zn_{(1-y)}Se/ZnS, CdS/ZnSe, CdS/ZnS/Cd_{y}Zn_{(1-y)}S/ZnS, CdSeₓS₍₁₋ₓ₎/CdS/ZnSe_{z}S_{(1-z)}, CdSeₓS₍₁₋ₓ₎/Cd_{y}Zn_{(1-y)}S, CdSeₓS₍₁₋ₓ₎/ZnSe_{z}S_{(1-z)}, CdSeₓS₍₁₋ₓ₎/Cd_{y}Zn_{(1-y)}S/ZnSe_{z}S_{(1-z)}, CdSeₓS₍₁₋ₓ₎/CdS, CdSeₓS₍₁₋ₓ₎/Cd_{y}Zn_{(1-y)}Se, CdSeₓS₍₁₋ₓ₎/ZnSe_{z}S_{(1-z)}, CdSeₓS₍₁₋ₓ₎/Cd_{y}Zn_{(1-y)}Se/ZnSe_{z}S_{(1-z)}, CdS/ZnSe_{z}S_{(1-z)}, CdSeₓS₍₁₋ₓ₎/ZnSe_{z}S_{(1-z)}/Cd_{y}Zn_{(1-y)}S/ZnS, CdSeₓS₍₁₋ₓ₎/ZnSe_{z}S_{(1-z)}/Cd_{y}Zn_{(1-y)}S/ZnSe_{z}S_{(1-z)}, CdS/Cd_{y}Zn_{(1-y)}S, CdS/Cd_{y}Zn_{(1-y)}S/ZnSe_{z}S_{(1-z)}, CdS/Cd_{y}Zn_{(1-y)}Se, CdS/ZnSe_{z}S_{(1-z)}, CdS/ZnSe_{z}S_{(1-z)}/Cd_{y}Zn_{(1-y)}S/ZnS, CdS/ZnSe_{z}S_{(1-z)}/Cd_{y}Zn_{(1-y)}S/ZnSe_{z}S_{(1-z)}, CdS/ZnS/Cd_{y}Zn_{(1-y)}S/ZnSe_{z}S_{(1-z)}, Cd_{y}Zn_{(1-y)}Se/ZnSe/ZnSe_{z}S_{(1-z)}/ZnS where x, y and z are rational numbers between 0 (excluded) and 1 (excluded), and emit green light when stimulated electrically. Emitted green light is typically a band centered on a wavelength shorter than 600 nm and longer than 500 nm, preferably shorter than 550 nm and longer than 520 nm, more preferably shorter than 535 nm and longer than 525 nm. Emitted green light is typically a band having a FWHM less than 50 nm, preferably less than 30 nm, more preferably less than 20 nm. Suitable semiconductor nanoparticles emitting green light at 530 nm are core/shell/shell nanoplatelets of CdSe_{0.10}S_{0.90}/ZnS/Cd_{0.20}Zn_{0.80}S, with a core of thickness 1.5 nm and a lateral dimension, i.e. length or width, greater than 10 nm and shells of thicknesses 1 nm and 2.5 nm. Other suitable semiconductor nanoparticles emitting green light at 530 nm are core/shell/shell nanoplatelets of CdSe_{0.20}S_{0.80}/ZnS/Cd_{0.15}Zn_{0.85}S, with a core of thickness 1.2 nm and a lateral dimension, i.e. length or width, greater than 10 nm and shells of thicknesses 1 nm and 2.5 nm.

In a configuration of this embodiment, semiconductor nanoparticles are selected from CdS/ZnSe, CdS/ZnS, CdS/Cd_{y}Zn_{(1-y)}S, CdS/Cd_{y}Zn_{(1-y)}S/ZnS, CdS/Cd_{y}Zn_{(1-y)}Se, CdS/Cd_{y}Zn_{(1-y)}Se/ZnSe, CdS/Cd_{y}Zn_{(1-y)}Se/ZnS, CdS/ZnS/Cd_{y}Zn_{(1-y)}S/ZnS, CdS/ZnSe_{z}S_{(1-z)}, CdS/Cd_{y}Zn_{(1-y)}S, CdS/Cd_{y}Zn_{(1-y)}S/ZnSe_{z}S_{(1-z)}, CdS/Cd_{y}Zn_{(1-y)}Se, CdS/ZnSe_{z}S_{(1-z)}, CdS/ZnSe_{z}S_{(1-z)}/Cd_{y}Zn_{(1-y)}S/ZnS, CdS/ZnSe_{z}S_{(1-z)}/Cd_{y}Zn_{(1-y)}S/ZnSe_{z}S_{(1-z)}, CdS/ZnS/Cd_{y}Zn_{(1-y)}S/ZnSe_{z}S_{(1-z)}, where x, y and z are rational numbers between 0 (excluded) and 1 (excluded), and emit blue light when stimulated electrically. Emitted blue light is typically a band centered on a wavelength shorter than 500 nm and longer than 400 nm, preferably shorter than 480 nm and longer than 420 nm, more preferably shorter than 455 nm and longer than 435 nm. Emitted blue light is typically a band having a FWHM less than 50 nm, preferably less than 30 nm, more preferably less than 20 nm. Suitable semiconductor nanoparticles emitting blue light at 450 nm are core/shell nanoplatelets of CdS/ZnS, with a core of thickness 0.9 nm and a lateral dimension, i.e. length or width, greater than 15 nm and a shell of thickness 1 nm.

In another embodiment, semiconductor nanoparticles have a longest dimension greater than 25 nm, preferably greater than 35 nm, more preferably greater than 50 nm. Actually, the association of anisotropy and a size larger than 25 nm along the longest dimension is favorable for deposition of semiconductor nanoparticles on substrate, in particular under di-electrophoretic conditions. It has been observed that larger particles are deposited quicker than smaller one. Besides, under di-electrophoretic conditions electro-rotation phenomenon takes place and leads to deposition in an oriented manner. In the specific configuration in which semiconductor nanoparticles are nanoplatelets deposited in an oriented manner and having their smallest face on the substrate, light emitted by the semiconductor nanoparticles is linearly polarized in a direction perpendicular to direction of orientation of the semiconductor nanoparticles. This is particularly advantageous in devices like display in which polarizing filters are used.

In another embodiment, semiconductor nanoparticles are on the substrate with their longest dimension substantially aligned in a predetermined direction. Such orientation of semiconductor nanoparticles allows for compact deposition, which has three advantages. First, thickness of deposit is reduced for a same quantity of semiconductor nanoparticles deposited and a thin electro-luminescent film is desirable for manufacturing reasons. Second, compact deposit enhances electric contact between semiconductor nanoparticles, such contacts being crucial to inject electricity in all semiconductor nanoparticles. Indeed, with a compact deposit, one can expect an improved yield of light emission for a same amount of electricity injected in semiconductor nanoparticles. Last, a good vertical stacking and assembly of semiconductor nanoparticles permit a better control of the thickness of the electro-luminescent layer. In this embodiment, “substantially aligned in a predetermined direction” means that at least X=50% of the nanoparticles are aligned in a predetermined direction, preferably at least 60% of the nanoparticles are aligned in a predetermined direction, more preferably at least 70% of the nanoparticles are aligned in a predetermined direction, most preferably at least 90% of the nanoparticles are aligned in a predetermined direction.

In another embodiment, substrate is selected from a conductive material and a semi-conductive material, preferably in the form of a layer of conductive material and a semi-conductive material. Indeed, substrate must enable electric current injection into semiconductor nanoparticles that are on substrate. Said conductive or semi-conductive layer is preferably under the form of a network enabling electric injection of current in each repetition unit independently, and preferably in each pixel of each repetition unit independently.

Conductive or semi-conductive material may be selected from Indium Tin Oxide (ITO), Aluminum doped Zinc Oxide (AZO), Fluorine doped Zinc Oxide (FZO), Graphene or other allotropic forms of carbon, Silver nanowires meshes, Silicon, Silicon on Insulator (SOI), Germanium on Insulator (GOI), Silicon-Germanium on insulator (SGOI), Doped Silicon substrates. It's worth noting that limit between conductive and semi-conductive materials is sometimes difficult to define, in particular with doped materials whose conductive properties are dependent upon doping concentration.

A specific embodiment of semi-conductive substrate is a conductive substrate on which a very thin layer of non-conductive, i.e. insulating material is located. Preferably, this very thin layer of non-conductive material is an electret material. The non-conductive layer is thin enough to allow for electric current injection through said non-conductive layer. Acceptable thickness for said non-conductive layer depends on insulating material, but is preferably less than 200 nm.

Suitable electret material may be selected from polymers, for example: Fluorinated Ethylene Propylene (FEP), Polytetrafluoroethylene (PTFE), Polyethylene (PE), Polycarbonate (PC), Polypropylene (PP), Poly Vinylchloride (PVC), Polyethylene Terephtalate (PET), Polyimide (PI), Polymethyl Methacrylate (PMMA), Polyvinyl fluoride (PVF), Polyvinylidene Fluoride (PVDF), Polydimethylsiloxane (PDMS), Ethylene Vinyl Acetate (EVA), Cyclic Olefin Copolymers (COC), Polyparaxylylène (PPX), Fluorinated parylenes and fluorinated polymers in amorphous form.

Other suitable electret materials may be selected from inorganic materials, for example: Silicon Oxide (SiO₂), Silicon Nitride (Si₃N₄), Aluminium oxide (Al₂O₃) or other doped mineral glass with known dopant atoms (as example Na, S, Se, B).

For instance, a layer of Silicon, optionally doped, with a thin layer of 100 nm of polymethylmethacrylate polymer (PMMA) is suitable as substrate.

In another embodiment, substrate is a soft material, for instance a non-conductive polymeric material, preferably an electret material, configured to be transferred on a semi-conductive or conductive support. By transferred, it is meant any method yielding a structure comprising said soft material on the semi-conductive or conductive support. Transfer may be direct, without any material between substrate and support: this is a direct contact between the substrate and the support. Transfer may use an adhesive between substrate and support, preferably a conductive adhesive. Transfer may use an intermediate carrier. This embodiment enables production of large pieces of substrate which may be stored for some time before being cut on demand and reported on semi-conductive or conductive supports.

In another embodiment, semiconductor nanoparticles on the substrate form layers with a thickness of less than 100 nm. Preferably, the thickness is ranging between 10 nm and 50 nm. Indeed, low thicknesses are preferred to design electronic devices, in particular for electro-luminescent devices where too long charges path could enhance non-radiative recombination. Moreover, too thick optical layers could enhance undesired optical reabsorption of emitted light.

In another embodiment, the volume fraction of semiconductor nanoparticles deposed on a pixel is ranging from 10% to 90%, preferably from 20% to 90%, more preferably from 30% to 90%, most preferably from 50% to 90%.

In another embodiment, a pixel comprises a density of semiconductor nanoparticles per surface unit greater than 5×10⁹ nanoparticles.cm⁻², preferably greater than 7×10⁹ nanoparticles.cm⁻², more preferably greater than 5×10¹⁰ nanoparticles.cm⁻², most preferably greater than 5×10¹¹ nanoparticles.cm⁻². The density of semiconductor nanoparticles per surface unit in a pixel refers to the number of semiconductor nanoparticles per volume unit in a pixel multiplied by the thickness of the layer of semiconductor nanoparticles on said pixel. A high density of semiconductor nanoparticles is preferred because it allows a close contact between semiconductor nanoparticles which is essential in the electro-luminescent film. A high density of semiconductor nanoparticles is preferred also because the film is more uniform, compact and without cracks. A high density of semiconductor nanoparticles is also preferred as it allows a high EQE (External Quantum Efficiency), in particular an EQE higher than 5%, preferably higher than 10%, more preferably higher than 20%.

In another embodiment, a pixel comprises at least 3×10¹⁴ nanoparticles.cm⁻³, preferably at least 5×10¹⁴ nanoparticles.cm⁻³, more preferably at least 5×10¹⁵ nanoparticles.cm⁻³, most preferably at least 1×10¹⁷ nanoparticles.cm⁻³.

In another embodiment, the repetition unit of the periodic pattern comprises at least two pixels. In particular, semiconductor nanoparticles on the first pixel of the at least two pixels are different from semiconductor nanoparticles on the second pixel of the at least two pixels. With such a configuration, the electro-luminescent film emits two different lights allowing for dichromatic device. In a preferred embodiment, the periodic pattern comprises three pixels comprising each one type of semiconductor nanoparticles, said three types of semiconductor nanoparticles being different. In particular, a first pixel comprising semiconductor nanoparticles with light emission in blue range, a second pixel comprising semiconductor nanoparticles with light emission in green range and a third pixel comprising semiconductor nanoparticles with light emission in red range is preferred.

The invention aims also at manufacturing electro-luminescent films. In order to deposit semiconductor nanoparticles on substrate, di-electrophoretic forces may be used. Said forces result in attraction of a polarizable object placed in an electric field produced by an electrically polarized surface. In addition, precision of deposition, i.e. definition of limits between areas where semiconductor nanoparticles are deposited and areas where no deposition occurs, is improved.

Semiconductor nanoparticles of the invention are polarizable. Preferably, semiconductor nanoparticles are neutral, i.e. not charged with permanent electric charges. In particular, anisotropic semiconducting nanoparticles are subject to strong di-electrophoretic forces considering that the physical dependence is proportional to the third power of the bigger dimension of the nanoparticles. Quantum Dots are limited in size by the emission wavelength, but Quantum Plates could be synthetized with longer dimensions (width and length) respect to the thickness (which controls the emission wavelength).

Therefore, invention also relates to a process for the manufacture of an electro-luminescent film comprising a substrate and semiconductor nanoparticles distributed on the substrate according to a periodic pattern, wherein the repetition unit of the pattern has a smallest dimension of less than 500 micrometer and comprises at least one pixel comprising the steps of:
i) Providing a substrate;
ii) Creating a surface electric potential on the substrate according to the pattern, so that at least one pixel of the repetition unit is created in the whole pattern; and
iii) Bringing the substrate in contact with a colloidal dispersion of semiconductor nanoparticles having an aspect ratio greater than 1.5 for a contacting time of less than 15 minutes.

During semiconductor nanoparticles deposition, substrate needs to be electrically polarized. This polarization may be permanent or induced.

Permanent polarization exists in materials known as electret: after application of an electric field to an electret material, a permanent electrical polarization remains. With electret material, it is possible to write a surface electric potential then to deposit semiconductor nanoparticles.

In this embodiment, the invention relates to a process for the manufacture of an electro-luminescent film comprising a substrate and semiconductor nanoparticles distributed on the substrate according to a periodic pattern, wherein the repetition unit of the pattern has a smallest dimension of less than 500 micrometer and comprises at least one pixel comprising the following steps.

In a first step, providing an electret substrate. The substrate may be any embodiment of substrate as defined above in the detailed description of the electro-luminescent film of the invention. A preferred substrate has an external layer of PMMA, i.e. the substrate is PMMA or the substrate is a conductive or semi-conductive material under a layer of PMMA.

In a second step, writing a surface electric potential on the electret substrate according to the pattern, so that at least one pixel of the repetition unit is written in the whole pattern.

Then, in a third step, the electret substrate is brought in contact with a colloidal dispersion of semiconductor nanoparticles having an aspect ratio greater than 1.5 for a contacting time of less than 15 minutes. Due to electric polarization density of electret, a di-electrophoretic force is imposed to semiconductor nanoparticles which are thus attracted towards the surface. As semiconductor nanoparticles are anisotropic, an electro-rotation effect takes place, yielding an improved deposition of semiconductor nanoparticles: deposit is denser, eventually semiconductor nanoparticles are oriented on the surface along a predetermined direction.

Contact may be done by immersion of electret substrate in a colloidal dispersion of semiconductor nanoparticles, preferably in a colloidal dispersion comprising semiconductor nanoparticles in an organic solvent, more preferably in a hydrocarbon solvent such as cyclohexane, hexane, heptane, decane or pentane.

Alternatively, contact may be done by drop-casting, spin coating, pouring a colloidal dispersion of semiconductor nanoparticles on the substrate, or by micro-fluidic contact system.

Alternatively, contact may be done by spraying micrometric droplets of colloidal dispersion of semiconductor nanoparticles in a flux of gas. Due to electric polarization density of electret, a di-electrophoretic force is imposed to semiconductor nanoparticles. It's worth noting that the solvent is preferably selected in non-polar solvent (such as for example heptane, pentane, hexane, decane), so that no di-electrophoretic forces are imposed to solvent and, moreover, electrical forces are reduced when the dielectric constant of the solvent is big, as in polar solvents. Micrometric droplets are thus attracted towards the surface. At the same time, drying occurs by evaporation of the solvent. As micrometric droplets are bigger than single semiconductor nanoparticles, the di-electrophoretic force effect is strongly increased yielding an improved deposition of semiconductor nanoparticles. This method enables coating of large surfaces of substrate and improves homogeneity and speed of deposition. Moreover, with a suitable calibration of the flow rate of the gas, a strong reduction of nanoparticle solution waste and reduction of cleaning processes are obtained.

All features of the electro-luminescent film of the invention, in particular of semiconductor nanoparticles may be implemented in said process.

In a variant of this embodiment, the invention also relates to a process for the manufacture of an electro-luminescent film comprising a substrate and semiconductor nanoparticles deposited on the substrate according to a periodic pattern, wherein the repetition unit of the pattern has a smallest dimension of less than 500 micrometer and comprises at least two pixels and wherein semiconductor nanoparticles on the first pixel of the at least two pixels are different from semiconductor nanoparticles on the second pixel of the at least two pixels comprising the following steps.

In a first step, providing an electret substrate. The substrate may be any embodiment of substrate as defined above in the detailed description of the electro-luminescent film of the invention. A preferred substrate has an external layer of PMMA, i.e. the substrate is PMMA or the substrate is a conductive or semi-conductive material under a layer of PMMA.

In a second step, writing a surface electric potential on the electret substrate according to the pattern, so that the first pixel of the repetition unit is written in the whole pattern.

In a third step, the electret substrate is brought in contact with a colloidal dispersion of semiconductor nanoparticles having an aspect ratio greater than 1.5 for a contacting time of less than 15 minutes.

Then, in a fourth step, electret substrate and semiconductor nanoparticles deposited thereon are dried to form an intermediate structure. Said intermediate structure can be treated as an electret substrate in the same manner as above if substrate surface has not been totally covered with semiconductor nanoparticles, i.e. if some surface of the electret substrate is still available to be electrically influenced, said surface is thus available for nanoparticles deposition.

In a fifth step, writing a surface electric potential on the intermediate structure according to the pattern, so that the second pixel of the repetition unit is written in the whole pattern.

The surface electric potential is written on parts of the surface on which no nanoparticles have been deposited during steps two to four.

In a sixth step, the electret substrate is brought in contact with a colloidal dispersion of semiconductor nanoparticles an aspect ratio greater than 1.5 and different from those used in third step for a contacting time of less than 15 minutes.

In some embodiments, steps four to six may be reiterated to yield a third pixel, a fourth pixel, without other limit than the definition of the repetition unit and pixels.

In steps three and six, contact may be done by immersion of electret substrate in a colloidal dispersion of semiconductor nanoparticles or by spraying micrometric droplets as described above.

Alternatively, contact may be done by drop-casting, spin coating, pouring a colloidal dispersion of semiconductor nanoparticles on the substrate, or by micro-fluidic contact system.

All features of the electro-luminescent film of the invention, in particular of semiconductor nanoparticles may be implemented in said process.

Besides processes using electret substrate having a permanent polarization, other processes use induced polarization.

Induced polarization corresponds to materials in which electrical polarization results from application of an external electrical field. As soon as external field is removed, electrical polarization disappears. In this case, it is possible to induce a surface electric potential and deposit semiconductor nanoparticles while surface electric potential is maintained.

In this embodiment, the invention relates to a process for the manufacture of an electro-luminescent film comprising a substrate and semiconductor nanoparticles distributed on the substrate according to a periodic pattern, wherein the repetition unit of the pattern has a smallest dimension of less than 500 micrometer and comprises at least one pixel comprising the following steps.

In a first step, providing a substrate. The substrate may be any embodiment of substrate as defined above in the detailed description of the electro-luminescent film of the invention.

In a second step, inducing a surface electric potential on the substrate according to the pattern, so that at least one pixel of the repetition unit is induced in the whole pattern.

Then, in a third step, the substrate is brought in contact with a colloidal dispersion of semiconductor nanoparticles having an aspect ratio greater than 1.5 for a contacting time of less than 15 minutes, while surface electric potential is maintained. Due to electric polarization density of substrate, a di-electrophoretic force is imposed to semiconductor nanoparticles which are thus attracted towards the surface. As semiconductor nanoparticles are anisotropic, an electro-rotation effect takes place, yielding an improved deposition of semiconductor nanoparticles: deposit is denser, eventually semiconductor nanoparticles are oriented on the surface along a predetermined direction.

Contact may be done by immersion of substrate in a colloidal dispersion of semiconductor nanoparticles, preferably in a colloidal dispersion comprising semiconductor nanoparticles in an organic solvent, more preferably in a hydrocarbon solvent such as cyclohexane, hexane, heptane or pentane.

Alternatively, contact may be done by drop-casting, spin coating, pouring a colloidal dispersion of semiconductor nanoparticles on the substrate, or by micro-fluidic contact system.

Alternatively, contact may be done by spraying micrometric droplets of colloidal dispersion of semiconductor nanoparticles in a flux of gas. Due to electric polarization density of substrate, a di-electrophoretic force is imposed to semiconductor nanoparticles. It's worth noting that the solvent is preferably selected in non-polar solvent, so that no di-electrophoretic forces are imposed to solvent. Micrometric droplets are thus attracted towards the surface. At the same time, drying occurs by evaporation of the solvent. As micrometric droplets are bigger than single semiconductor nanoparticles, the di-electrophoretic force effect is strongly increased yielding an improved deposition of semiconductor nanoparticles. This method enables coating of large surfaces of substrate and improves homogeneity and speed of deposition. Moreover, with a suitable calibration of the flow rate of the gas, a strong reduction of nanoparticle solution waste and reduction of cleaning processes are obtained.

During third step, one has to simultaneously maintain surface electric potential and bring in contact the substrate with the colloidal suspension. The device used to induce surface electric potential may be located on side of the substrate on which semiconductor nanoparticles are deposited. Alternatively, the device used to induce surface electric potential may be located on the opposite side of the substrate's side on which semiconductor nanoparticles are deposited. This second configuration is preferred as contact between colloidal suspension and device used to induce surface electric potential is avoided. However, this configuration requires that substrate is not too thick: a thickness less than 50 μm, preferably less than 20 μm is preferred and allow improved precision of deposition.

All features of the electro-luminescent film of the invention, in particular of semiconductor nanoparticles may be implemented in said process.

In a variant of this embodiment, the invention also relates to a process for the manufacture of an electro-luminescent film comprising a substrate and semiconductor nanoparticles deposited on the substrate according to a periodic pattern, wherein the repetition unit of the pattern has a smallest dimension of less than 500 micrometer and comprises at least two pixels and wherein semiconductor nanoparticles on the first pixel of the at least two pixels are different from semiconductor nanoparticles on the second pixel of the at least two pixels comprising the following steps.

In a first step, providing a substrate. The substrate may be any embodiment of substrate as defined above in the detailed description of the electro-luminescent film of the invention.

In a second step, inducing a surface electric potential on the substrate according to the pattern, so that the first pixel of the repetition unit is induced in the whole pattern.

In a third step, the substrate is brought in contact with a colloidal dispersion of semiconductor nanoparticles having an aspect ratio greater than 1.5 for a contacting time of less than 15 minutes, while surface electric potential is maintained.

Then, in a fourth step, substrate and semiconductor nanoparticles deposited thereon are dried to form an intermediate structure. Said intermediate structure can be treated as a substrate in the same manner as above if substrate surface has not been totally covered with semiconductor nanoparticles, i.e. if some surface of the substrate is still available to be electrically influenced, said surface is thus available for nanoparticles deposition.

In a fifth step, inducing a surface electric potential on the intermediate structure according to the pattern, so that the second pixel of the repetition unit is induced in the whole pattern. The surface electric potential is induced on parts of the surface on which no nanoparticles have been deposited during steps two to four.

In a sixth step, the substrate is brought in contact with a colloidal dispersion of semiconductor nanoparticles an aspect ratio greater than 1.5 and different from those used in third step for a contacting time of less than 15 minutes, while surface electric potential is maintained.

During third and sixth steps, one has to simultaneously maintain surface electric potential and bring in contact substrate with colloidal suspension. The device used to induce surface electric potential may be located on side of the substrate on which semiconductor nanoparticles are deposited. Alternatively, the device used to induce surface electric potential may be located on the opposite side of the substrate's side on which semiconductor nanoparticles are deposited. This second configuration is preferred as contact between colloidal suspension and device used to induce surface electric potential is avoided. However, this configuration requires that substrate is not too thick: a thickness less than 50 μm, preferably less than 20 μm is preferred and allow improved precision of deposition.

In some embodiments, steps four to six may be reiterated to yield a third pixel, a fourth pixel, without other limit than the definition of the repetition unit and pixels.

In steps three and six, contact may be done by immersion of substrate in a colloidal dispersion of semiconductor nanoparticles or by spraying micrometric droplets as described above.

All features of the electro-luminescent film of the invention, in particular of semiconductor nanoparticles may be implemented in said process.

The invention also relates to a light emitting device comprising an electro-luminescent film comprising a substrate and semiconductor nanoparticles on the substrate according to a periodic pattern, wherein semiconductor nanoparticles have an aspect ratio greater than 1.5; wherein the repetition unit of the pattern has a smallest dimension of less than 500 micrometer and comprises at least one pixel. All embodiments of the electro-luminescent film of the invention may be implemented in said light emitting device.

While various embodiments have been described and illustrated, the detailed description is not to be construed as being limited hereto. Various modifications can be made to the embodiments by those skilled in the art without departing from the true spirit and scope of the disclosure as defined by the claims.

### BRIEF DESCRIPTION OF THE DRAWINGS

FIG. 1 illustrates a schematic of an electro-luminescent film (1) comprising a substrate (2). A periodic pattern (here a rectangular lattice) is shown as a network of dotted lines. At each node of the network, a repetition unit (3) of rectangular shape is shown (delimited by a bold dotted line). Smallest size of repetition unit is noted S. In repetition unit are shown three pixels of square section (4a), (4b) and (4c). Semiconductor nanoparticles (not shown) are on the substrate (2), in the volume of each pixel.

FIG. 2 illustrates an anisotropic nanoparticle, here a nanoplatelet, and defines aspect ratio.

FIG. 3 shows microscopy images of nanoplatelets used in example 1. Scale bars are 10 nm (3a), 10 nm (3b) and 5 nm (3c).

FIG. 4 shows emission spectrum (arbitrary unit) of nanoplatelets used in example 1 (emitting in red range: dashed line, green range: dotted line and blue range: solid line) as a function of light wavelength (λ in nanometer).

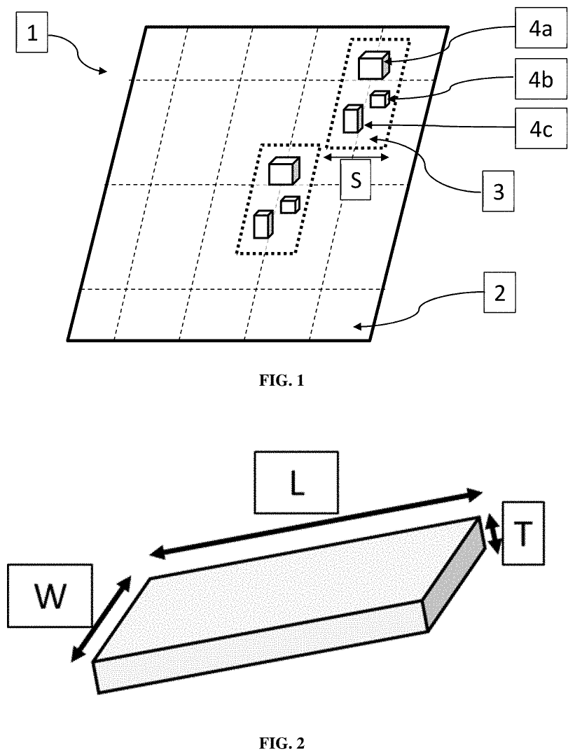

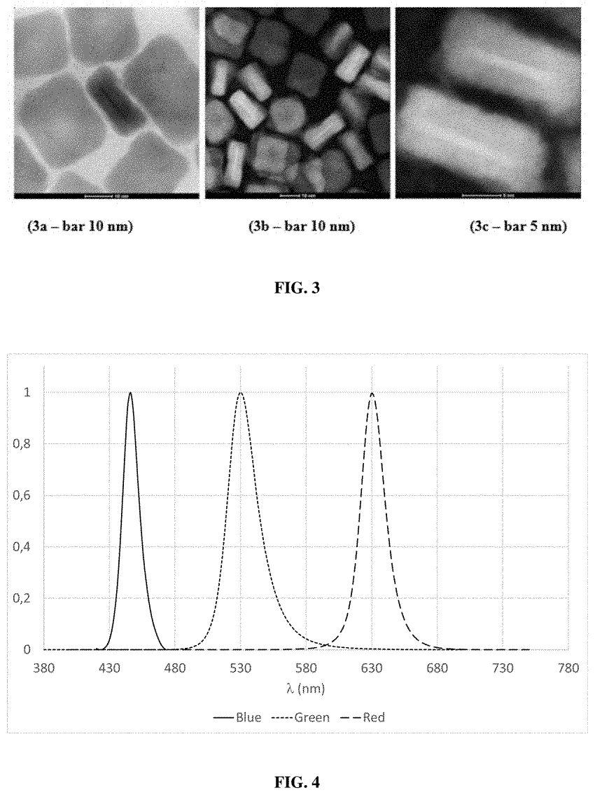

### EXAMPLES

The present invention is further illustrated by the following examples.

### Example 1

Preparation of a Stamp:

A photolithographic mask is fabricated on a UV-blue transparent substrate to reproduce a pattern with squared pixels of 5 μm size distributed on a square lattice of period 15 μm. A silicon carrier is covered by a uniform photolithography resin and illuminated by an UV lamp producing a 350 nm light filtered by the lithography mask in order to impress the pattern on the carrier. A proper washing solution for the resin is utilized to develop the polymer and create a tridimensional motif (pixelization).

A PDMS solution is casted on this tridimensional motif and the silicon carrier, then heated at 150° C. for 24 h to assure the polymerization of the PDMS. The solidified PDMS is thus separated from the silicon carrier. The so patterned PDMS is gold covered by evaporation technique to ensure a conductive pixelated surface. The patterned and conductive PDMS substrate is now called the stamp. It consists of a planar conductive surface on which square pixels of 5 μm size and 20 μm height are distributed on a square lattice. The stamp is a square of size 5 cm.

Preparation of Substrate:

A p-doped silicon wafer substrate of 375 μm thickness is used to cast by spin coating a 200 nm thick PMMA solid film by using a solution of 5% in weight of PMMA (Mw: 10⁶ g·mol⁻¹) in toluene.

Preparation of Nanoparticles Colloidal Dispersions:

A solution A comprising 10⁻⁸ mole·L⁻¹ CdSe_{0.45}S_{0.55}/CdZnS/ZnS nanoplatelets in cyclohexane is prepared. These nanoplatelets are 25 nm long, 20 nm wide and 9 nm thick (core: 1.2 nm; first shell: 2 nm; second shell: 2 nm) and emit at 630 nm with FWHM of 20 nm.

A solution B comprising 10⁻⁸ mole·L⁻¹ CdSe_{0.10}S_{0.90}/ZnS/Cd_{0.20}Zn_{0.80}S nanoplatelets in cyclohexane is prepared. These nanoplatelets are 25 nm long, 20 nm wide and 8.5 nm thick (core: 1.5 nm; first shell: 1 nm; second shell: 2.5 nm) and emit at 530 nm with FWHM of 30 nm.

A solution C comprising 10⁻⁸ mole·L⁻¹ CdS/ZnS nanoplatelets in cyclohexane is prepared. These nanoplatelets are 25 nm long, 20 nm wide and 3 nm thick (core: 0.9 nm; first shell: 1 nm) and emit at 445 nm with FWHM of 20 nm.

Emission spectra of semiconductor nanoparticles from solution A, B and C are shown in FIG. 4.

Preparation of Electro-Luminescent Film:

The substrate is put in contact with the stamp in order to create a capacitive system with the PMMA in the middle (between stamp and p-doped silicon) as dielectric medium. A voltage of 50 V is applied for 1 minute in order to create permanent electrical polarization in the PMMA layer (electret material) only in correspondence with the pixels of the stamp.

To maintain stable the charges on the electret, humidity level of the environment is kept below 50%.

Substrate with electrically polarized PMMA layer is dipped in solution A for 10 seconds then rinsed by a clean solvent and dried by a gentle flux of nitrogen.

Using a microscopic technique of alignment, the stamp is then again placed on the already red pixelated substrate, with pixels of the stamp defining a second pixel on the substrate (different from the red pixel) according to the original periodic patterning chosen. A voltage of 50 V is applied again for 1 minute in order to create permanent electrical polarization in the PMMA layer only in correspondence with the pixels of the stamp, i.e. in correspondence with areas free of nanoparticles.

Substrate with electrically polarized PMMA layer is dipped in solution B for 10 seconds then rinsed by a clean solvent and dried by a gentle flux of nitrogen.

Using the same microscopic technique of alignment, the stamp is then again placed on the already red/green pixelated substrate, with pixels of the stamp defining a third pixel on the substrate (different from the red and green pixels) according to the original periodic patterning chosen. A voltage of 50 V is applied again for 1 minute in order to create permanent electrical polarization in the PMMA layer only in correspondence with the pixels of the stamp.

Substrate with electrically polarized PMMA layer is dipped in solution C for 10 seconds then rinsed by a clean solvent and dried by a gentle flux of nitrogen.

Electro-Luminescent Film and Device:

A 25 cm² substrate of p-doped silicon coated with a 200 nm PMMA layer with square pixels of 5 μm size and three different types (red, green and blue emitting semiconductor nanoparticles) distributed on a square lattice of period 15 μm is obtained, forming an electro-luminescent film.

Below the substrate, all necessary other layers and electrical contacts needed for the injection of electric current in each pixel are built by well know techniques in the microelectronic industry of semiconductors, yielding an electro-luminescent device.

### Example 2

Example 1 is reproduced, except that periodic pattern is changed.

In example 2a, pixels are square with 3 μm size and square lattice has a period of 12 μm.

In example 2b, four squared pixels of size 5 μm are defined on a square lattice of period 15 μm, with one red pixel, two green pixels and one blue pixel.

### Example 3

Example 1 is reproduced, except that substrate is changed.

Example 3a: Silicon On Insulator (SOI) having the following structure: Silicon (15 nm)-Insulator (200 nm)-Silicon (200 nm) is used.

Example 3b: on a glass substrate with TFT matrix are deposited successively the following layers:
1. a common buried electrode for the periodic array of capacitance in step 3;
2. a 300 nm silicon oxide insulator;
3. a periodic array of separately isolated bottom electrode (each configured to make a diode); and
4. optionally an electron transporting layer for each pixel.

Example 3c: a LCD glass substrate with TFT matrix are deposited successively the following layers:
1. a periodic array of bottom electrode;
2. a ZnO electron transporting layer for each pixel; and
3. a PMMA layer of 7 nm.

The same deposition method yields electro-luminescent films which can be implemented as electro-luminescent devices using well know techniques in the microelectronic industry of semiconductors.

### Example 4-1

Example 1 is reproduced, except that semiconductor nanoparticles are changed.

A solution D comprising 10⁻⁸ mole·L⁻¹ CdSe_{0.45}S_{0.55}/Cd_{0.30}Zn_{0.70}S/ZnS nanoplatelets in cyclohexane is prepared. These nanoplatelets are 35 nm long, 25 nm wide and 10.2 nm thick (core: 1.2 nm; first shell: 2.5 nm; second shell: 2 nm) and emit at 630 nm with FWHM of 25 nm.

After dipping of substrate with electrically polarized PMMA layer in solution D instead of solution A, nanoparticle deposition is observed as for example 1. It is observed that deposition is obtained in shorter exposure time, namely 4 seconds instead of 10 seconds.

### Example 4-2

Example 1 is reproduced, except that semiconductor nanoparticles are changed.

TABLE I
Colloidal dispersions of semiconductor nanoparticles used for deposition on substrate.
(MLs refers to the number of monolayers of inorganic material covering the core).

| | Dimensions | | | | | | |
|---|---|---|---|---|---|---|---|
| | L | W | T | [NPs] | Emission | | |
| Nanoparticles (NPs) | (nm) | (nm) | (nm) | (mol · L⁻¹) | peak | FWHM | Deposition |

CORE/SHELL NANOPLATELETS

| | | | | | | | |
|---|---|---|---|---|---|---|---|
| CdS/ZnS 5 MLs | 17 | 17 | 3.2 | 5 × 10⁻⁶ | 465 nm | 14 nm | observed |
| CdS/ZnSe_{0.5}S_{0.5} 5 MLs | 15 | 15 | 3.2 | 2 × 10⁻⁶ | 465 nm | 15 nm | observed |
| CdS/ZnSe 5 MLs | 17 | 17 | 3.5 | 1 × 10⁻⁶ | 460 nm | 15 nm | observed |
| CdSe_{0.30}S_{0.70}/ZnS 5 MLs | 25 | 20 | 3.1 | 0.2 × 10⁻⁶ | 535 nm | 28 nm | observed |
| CdSe_{0.25}S_{0.75}/Cd_{0.05}Zn_{0.95}S | 27 | 22 | 3.4 | 2 × 10⁻⁶ | 550 nm | 30 nm | observed |
| CdSe_{0.20}S_{0.80}/ZnSe 5 MLs | 24 | 18 | 3.0 | 2 × 10⁻⁶ | 540 nm | 29 nm | observed |
| CdSe_{0.20}S_{0.80}/ZnSe_{0.50}S_{0.50} | 26 | 20 | 3.3 | 0.5 × 10⁻⁶ | 530 nm | 30 nm | observed |
| 5 MLs | | | | | | | |
| CdSe_{0.83}S_{0.17}/Cd_{0.50}Zn_{0.50}S | 28 | 18 | 5 | 1 × 10⁻⁶ | 621 nm | 29 nm | observed |
| 4 MLs | | | | | | | |
| CdSe/Cd_{0.1}Zn_{0.9}S 4 MLs | 16 | 17 | 4.9 | 2 × 10⁻⁶ | 625 nm | 22 nm | observed |
| CdSe_{0.75}S_{0.25}/Cd_{0.50}Zn_{0.50}S | 30 | 20 | 4.8 | 4 × 10⁻⁶ | 645 nm | 26 nm | observed |
| 4 MLs | | | | | | | |
| CdSe/ZnSe_{0.50}S_{0.50} 4 MLs | 17 | 17 | 4 | 2 × 10⁻⁶ | 645 nm | 28 nm | observed |
| CdSe/ZnS 4 MLs | 17 | 17 | 4 | 3.5 × 10⁻⁶ | 617 nm | 27 nm | observed |

CORE/SHELL/SHELL NANOPLATELETS

| | | | | | | | |
|---|---|---|---|---|---|---|---|
| ZnSe/ZnSe_{0.4}S_{0.6}/ZnS | 50 | 20 | 3.2 | 20 × 10⁻⁶ | 445 nm | 15 nm | observed |
| CdSe_{0.90}S_{0.10}/ZnSe/ZnS | 27 | 19 | 5 | 2 × 10⁻⁶ | 650 nm | 28 nm | observed |
| 4 MLs | | | | | | | |

CORE/CROWN NANOPLATELETS

| | | | | | | | |
|---|---|---|---|---|---|---|---|
| CdSe/CdS 3 MLs | 20 | 12 | 0.9 | 3 × 10⁻⁶ | 465 nm | 10 nm | observed |
| CdS/ZnSe 5 MLs | 15 | 15 | 1.2 | 2 × 10⁻⁶ | 468 nm | 15 nm | observed |
| CdSe/CdS 4 MLs | 15 | 15 | 1.2 | 2 × 10⁻⁶ | 515 nm | 10 nm | observed |
| CdSe_{0.90}S_{0.10}/CdS 5 MLs | 27 | 21 | 1.5 | 2.5 × 10⁻⁶ | 540 nm | 14 nm | observed |
| CdSe/CdS 5 MLs | 26 | 17 | 1.5 | 1 × 10⁻⁶ | 555 nm | 12 nm | observed |

DOT IN PLATE NANOPLATELETS (core: quantum dot, final nanoparticle: nanoplatelet)

| | | | | | | | |
|---|---|---|---|---|---|---|---|
| CdSe/CdS 3 MLs | 15 | 15 | 0.9 | 2.3 × 10⁻⁶ | 462 nm | 10 nm | observed |
| CdSe_{0.50}S_{0.50}/CdS/ZnS | 25 | 25 | 3.2 | 2 × 10⁻⁶ | 540 nm | 35 nm | observed |
| 4 MLs | | | | | | | |

CORE/CROWN/SHELL NANOPLATELETS

| | | | | | | | |
|---|---|---|---|---|---|---|---|
| CdS/ZnSe/ZnS 5 MLs | 17 | 17 | 3.5 | 2 × 10⁻⁶ | 550 nm | 30 nm | observed |
| CdSe_{0.30}S_{0.70}/CdS/ZnS | 27 | 20 | 3.4 | 10 × 10⁻⁶ | 550 nm | 30 nm | observed |
| 5 MLs | | | | | | | |

After dipping of substrate with electrically polarized PMMA layer in a colloidal dispersion of semiconductor nanoparticles listed in Table I instead of solution A, nanoparticle deposition is observed as for example 1.

### Example 5

Example 1 is reproduced, except that substrate and preparation of electro-luminescent film are changed.

Substrate is a 50 μm thick square glass slide of size 5 cm. Substrate is held horizontally.

The stamp is placed below the substrate and in contact with the substrate. A voltage of 50 V is applied in order to induce electrical polarization in the substrate only in correspondence with the pixels of the stamp.

While voltage is applied, a layer of solution A is poured on the top side of substrate and voltage is maintained for 10 seconds then shut off. Stamp is removed from bottom side of substrate and excess solution A is removed. Substrate is then rinsed by a clean solvent and dried by a gentle flux of nitrogen.

Using a microscopic technique of alignment, the stamp is then again placed below the already red pixelated substrate, with pixels of the stamp defining a second pixel on the substrate (different from the red pixel) according to the original periodic patterning chosen. A voltage of 50 V is applied in order to induce electrical polarization in correspondence with the pixels of the stamp.

While voltage is applied, a layer of solution B is poured on the top side of substrate and voltage is maintained for 10 seconds then shut off. Stamp is removed from bottom side of substrate and excess solution B is removed. Substrate is then rinsed by a clean solvent and dried by a gentle flux of nitrogen.

Using the same microscopic technique of alignment, the stamp is then again placed below the already red/green pixelated substrate, with pixels of the stamp defining a third pixel on the substrate (different from the red and green pixels) according to the original periodic patterning chosen. A voltage of 50 V is applied in order to induce electrical polarization in correspondence with the pixels of the stamp.

While voltage is applied, a layer of solution C is poured on the top side of substrate and voltage is maintained for 10 seconds then shut off. Stamp is removed from bottom side of substrate and excess solution C is removed. Substrate is then rinsed by a clean solvent and dried by a gentle flux of nitrogen.

### Comparative Example C1

Example 1 is reproduced, except that semiconductor nanoparticles are changed.

A solution C-A comprising 10⁻⁸ mole·L⁻¹ CdSe/CdS/ZnS nanoparticles in cyclohexane is prepared. These nanoparticles are spherical (aspect ratio of 1) with a diameter of 6 nm and emit at 620 nm with FWHM of 45 nm.

A solution C-B comprising 10⁻⁸ mole·L⁻¹ Cd_{0.10}Zn_{0.90}Se_{0.10}S_{0.90}/ZnS nanoparticles in cyclohexane is prepared. These nanoparticles are spherical (aspect ratio of 1) with a diameter of 6 nm and emit at 540 nm with FWHM of 37 nm.

After dipping of substrate with electrically polarized PMMA layer in solution C-A instead of A, no significant nanoparticle deposition is observed: isolated nanoparticles are found on the substrate, but they do not form a layer of nanoparticles. No selective deposition on the pattern occurs.

After dipping of substrate with electrically polarized PMMA layer in solution C-B instead of B, no significant nanoparticle deposition is observed: isolated nanoparticles are found on the substrate, but they do not form a layer of nanoparticles. No selective deposition on the pattern occurs.

Nanoparticles of solutions C-A and C-B are too small to form significant deposits on substrate.

Thus, the deposit with spherical nanoparticles of this size is not conclusive.

In addition, spherical nanoparticles emitting light in shorter wavelength, typically in blue range, are even smaller in diameter and it was not able to deposit these nanoparticles.

### Comparative Example C2

Example 1 is reproduced, except that semiconductor nanoparticles are changed.

A solution C-C comprising 10⁻⁸ mole·L⁻¹ CdSe/CdS/ZnS nanoparticles in cyclohexane is prepared. These nanoparticles are spherical (aspect ratio of 1) with a diameter of 3 nm and emit at 620 nm with FWHM of 45 nm.

A solution C-D comprising 10⁻⁸ mole·L⁻¹ Cd_{0.10}Zn_{0.90}Se_{0.10}S_{0.90}/ZnS nanoparticles in cyclohexane is prepared. These nanoparticles are spherical (aspect ratio of 1) with a diameter of 4 nm and emit at 540 nm with FWHM of 37 nm.

After dipping of substrate with electrically polarized PMMA layer in solution C-C instead of A, no significant nanoparticle deposition is observed: isolated nanoparticles are found on the substrate, but they do not form a layer of nanoparticles. No selective deposition on the pattern occurs.

After dipping of substrate with electrically polarized PMMA layer in solution C-D instead of B, no significant nanoparticle deposition is observed: isolated nanoparticles are found on the substrate, but they do not form a layer of nanoparticles. No selective deposition on the pattern occurs.

Thus, nanoparticles of solutions C-C and C-D do not form significant deposits on substrate because they are too small.

### Comparative Example C3

Example 1 is reproduced, except that semiconductor nanoparticles are changed.

A solution C-E comprising 10⁻⁸ mole·L⁻¹ of composite particles comprising CdSe_{0.45}S_{0.55}/CdZnS/ZnS nanoplatelets in SiO₂ matrix, in cyclohexane is prepared (nanoplatelets are 25 nm long, 20 nm wide and 9 nm thick). These composite particles are spherical (aspect ratio of 1) with a diameter of 100 nm and emit at 630 nm with FWHM of 20 nm.

A solution C-F comprising 10⁻⁸ mole·L⁻¹ of composite particles comprising CdSe_{0.10}S_{0.90}/ZnS/Cd_{0.20}Zn_{0.80}S nanoplatelets in Al₂O₃ matrix, in cyclohexane is prepared. These composite particles are spherical (aspect ratio of 1) with a diameter of 120 nm and emit at 530 nm with FWHM of 30 nm.

After dipping of substrate with electrically polarized PMMA layer in solution C-E instead of A, significant nanoparticle deposition is observed.

After dipping of substrate with electrically polarized PMMA layer in solution C-F instead of B, significant nanoparticle deposition is observed.

However, the deposition of composite particles of solutions C-E and C-F does not result in an electro-luminescent film because SiO₂ and Al₂O₃ encapsulating the semiconductor nanoplatelets act as insulating, thus no electricity can be transferred directly to the semiconductor nanoplatelets.

1.-14. (canceled)

15. An electro-luminescent film comprising a substrate and semiconductor nanoparticles distributed on the substrate according to a periodic pattern, wherein semiconductor nanoparticles have an aspect ratio greater than 1.5; wherein the repetition unit of the pattern has a smallest dimension of less than 500 micrometer and comprises at least one pixel.

16. The electro-luminescent film according to claim 15, wherein the pattern is periodic in two dimensions.

17. The electro-luminescent film according to claim 16, wherein the periodic pattern is a rectangular lattice or a square lattice.

18. The electro-luminescent film according to claim 15, wherein semiconductor nanoparticles are inorganic.

19. The electro-luminescent film according to claim 18, wherein semiconductor nanoparticles are semiconductor nanocrystals comprising a material of formula MₓQ_{y}E_{z}A_{w}, wherein: M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs; Q is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs; E is selected from the group consisting of O, S, Se, Te, C, N, P, As, Sb, F, Cl, Br, I; A is selected from the group consisting of O, S, Se, Te, C, N, P, As, Sb, F, Cl, Br, I; and x, y, z and w are independently a rational number from 0 to 5; x, y, z and w are not simultaneously equal to 0; x and y are not simultaneously equal to 0; z and w are not simultaneously equal to 0.

20. The electro-luminescent film according to claim 15, wherein semiconductor nanoparticles have a longest dimension greater than 25 nanometers.

21. The electro-luminescent film according to claim 15, wherein semiconductor nanoparticles have a longest dimension greater than 35 nanometers.

22. The electro-luminescent film according to claim 15, wherein semiconductor nanoparticles are on the substrate with their longest dimension substantially aligned in a predetermined direction.

23. The electro-luminescent film according to claim 15, wherein substrate is selected from a conductive material and a semi-conductive material.

24. The electro-luminescent film according to claim 15, wherein semiconductor nanoparticles on the substrate form layers with a thickness of less than 100 nm.

25. The electro-luminescent film according to claim 15, wherein the repetition unit of the periodic pattern comprises at least two pixels.

26. The electro-luminescent film according to claim 25, wherein semiconductor nanoparticles on the first pixel of the at least two pixels are different from semiconductor nanoparticles on the second pixel of the at least two pixels.

27. A process for the manufacture of an electro-luminescent film comprising a substrate and semiconductor nanoparticles distributed on the substrate according to a periodic pattern, wherein the repetition unit of the pattern has a smallest dimension of less than 500 micrometer and comprises at least one pixel comprising the steps of:
i) providing a substrate;
ii) creating a surface electric potential on the substrate according to the pattern, so that at least one pixel of the repetition unit is created in the whole pattern; and
iii) bringing the substrate in contact with a colloidal dispersion of semiconductor nanoparticles having an aspect ratio greater than 1.5 for a contacting time of less than 15 minutes.

28. The process for the manufacture of an electro-luminescent film according to claim 27, wherein the substrate is an electret substrate and wherein the surface electric potential is written on the electret substrate.

29. The process for the manufacture of an electro-luminescent film according to claim 28, wherein the repetition unit of the pattern comprises at least two pixels and wherein semiconductor nanoparticles on the first pixel of the at least two pixels are different from semiconductor nanoparticles on the second pixel of the at least two pixels; and wherein process further comprises:
iv) drying the electret substrate and semiconductor nanoparticles deposited thereon to form an intermediate structure;
v) writing a surface electric potential on the intermediate structure according to the pattern, so that the second pixel of the repetition unit is written in the whole pattern; and
vi) bringing the electret substrate in contact with a colloidal dispersion of semiconductor nanoparticles having an aspect ratio greater than 1.5 and different from those used in step iii) for a contacting time of less than 15 minutes.

30. The process for the manufacture of an electro-luminescent film according to claim 27, wherein the surface electric potential is induced and maintained on the substrate during contact with colloidal dispersion.

31. The process for the manufacture of an electro-luminescent film according to claim 30, wherein the repetition unit of the pattern comprises at least two pixels and wherein semiconductor nanoparticles on the first pixel of the at least two pixels are different from semiconductor nanoparticles on the second pixel of the at least two pixels; and wherein process further comprises:
iv) drying the substrate and semiconductor nanoparticles deposited thereon to form an intermediate structure;
v) inducing a surface electric potential on the intermediate structure according to the pattern, so that the second pixel of the repetition unit is induced in the whole pattern; and
vi) bringing the electret substrate in contact with a colloidal dispersion of semiconductor nanoparticles having an aspect ratio greater than 1.5 and different from those used in step iii) for a contacting time of less than 15 minutes; while surface electric potential is maintained.

32. A light emitting device comprising an electro-luminescent film comprising a substrate and semiconductor nanoparticles on the substrate according to a periodic pattern, wherein semiconductor nanoparticles have an aspect ratio greater than 1.5; wherein the repetition unit of the pattern has a smallest dimension of less than 500 micrometer and comprises at least one pixel.
